(19) United States
(12) Patent Application Publication
(10) Pub. No.: US 2018/0123561 A1
(43) Pub. Date: May 3, 2018

(54) FILTER

(71) Applicant: SAMSUNG ELECTRO-MECHANICS CO., LTD., Suwon-si (KR)

(72) Inventors: Hyun Jun KIM, Suwon-si (KR); Won Kyu JEUNG, Suwon-si (KR)

(73) Assignee: SAMSUNG ELECTRO-MECHANICS CO., LTD., Suwon-si (KR)

(21) Appl. No.: 15/711,323

(22) Filed: Sep. 21, 2017

(30) Foreign Application Priority Data
Oct. 31, 2016 (KR) 10-2016-0143741
Mar. 27, 2017 (KR) 10-2017-0038370

(51) Int. Cl. H03H 9/54; H03H 9/205; H03H 9/56

(52) U.S. Cl. CPC H03H 9/205; H03H 9/568

(57) ABSTRACT

A filter includes a multilayer structure comprising films configured as bulk acoustic-wave resonators; and a cap member formed of glass or polymer, accommodating the bulk acoustic-wave resonators and bonded to the multilayer structure.

### CROSS-REFERENCE TO RELATED APPLICATION(S)

This application claims benefit of under 35 USC 119(a) of Korean Patent Application Nos. 10-2016-0143741 filed on Oct. 31, 2016 and 10-2017-0038370 Mar. 27, 2017 in the Korean Intellectual Property Office, the entire disclosure of which is incorporated herein by reference for all purposes.

### BACKGROUND

### 1. Field

The present disclosure relates to a filter.

### 2. Description of Related Art

Due to rapid development of mobile communications devices, chemical and biological devices, the demand for compact, lightweight filters, oscillators, resonant elements, and acoustic resonant mass sensors used in the above-mentioned devices has also recently increased.

As a means for implementing such compact, lightweight filters, oscillators, resonant elements, acoustic resonant mass sensors, and the like, a film bulk acoustic resonator (FBAR) is sometimes used. The film bulk acoustic resonator may be mass-produced at minimal cost and may be implemented in a very small size. Further, the film bulk acoustic resonator may be implemented to have a high quality factor Q value, a main property of a filter. The film bulk acoustic resonator can also be used in a micro-frequency band used in personal communications systems (PCS) and digital cordless systems (DCS).

Generally, the film bulk acoustic resonator has a structure including a resonating part implemented by sequentially stacking a first electrode, a piezoelectric layer, and a second electrode on a substrate. The operational principle of the film bulk acoustic resonator will be described hereinafter. First, an electric field is induced in the piezoelectric layer by electrical energy applied to the first and second electrodes, and a piezoelectric phenomenon occurs in the piezoelectric layer by the induced electric field. As a result, the resonating part vibrates in a predetermined direction and, a bulk acoustic wave is generated in the same direction as the vibration direction of the resonating part, such that resonance occurs.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a filter includes a multilayer structure comprising films configured as bulk acoustic-wave resonators; and a cap member formed of glass or polymer, accommodating the bulk acoustic-wave resonators and bonded to the multilayer structure.

The films may include a substrate, and a first electrode, a piezoelectric layer, and a second electrode, stacked on the substrate.

The substrate may be formed of silicon.

The cap member may be directly bonded to the substrate.

The cap member and the substrate may be bonded to each other through anodic bonding.

A shielding layer may be provided on a lower surface of the substrate.

The shielding layer may be formed in an electrode having a mesh structure.

The shielding layer may be configured to provide a reference potential.

In another general aspect, a filter includes a multilayer structure configured as bulk acoustic-wave resonators, a cap member and a shielding layer. Each of the bulk acoustic-wave resonators includes a substrate, a first electrode, a piezoelectric layer, and a second electrode, stacked on the substrate. The cap member accommodates the bulk acoustic-wave resonators, and is bonded to the multilayer structure. The shielding layer is configured on a lower surface of the substrate.

The shielding layer may be formed in an electrode having a mesh structure.

The shielding layer may be formed in an electrode having a solid structure.

The shielding layer may provide a reference potential.

The reference potential may correspond to a ground potential.

The cap member and the substrate may be directly bonded to each other through anodic bonding.

The cap member may be formed of glass.

The substrate may be formed of silicon.

The cap member may be formed of polymer.

In another general aspect, a filter includes a substrate, bulk acoustic-wave resonators disposed on the substrate, and a cap member formed of glass disposed to accommodate and seal the bulk acoustic-wave resonators. The cap member is bonded to the substrate.

A shielding layer having a mesh structure may be disposed on a lower surface of the substrate.

The cap member and the substrate may be bonded to each other through anodic bonding.

Other features and aspects will be apparent from the following detailed description, the drawings, and the claims.

### BRIEF DESCRIPTION OF DRAWINGS

FIG. 1 is a cross-sectional view illustrating an example of a filter.

FIG. 2 is a view provided to illustrate an example of an anodic bonding.

FIG. 3 is a bottom view of an example of a substrate.

FIG. 4 illustrates a simulation result according to an example in the present disclosure.

FIGS. 5 and 6 are schematic circuit diagrams of examples of a filter in the present disclosure.

Throughout the drawings and the detailed description, the same reference numerals refer to the same elements. The drawings not be to scale, and the relative size, proportions, and depiction of elements in the drawings be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but be changed as will be apparent after an understanding of the disclosure of this application, with the exception of operations necessarily occurring in a certain order. Also, descriptions of features that are known in the art be omitted for increased clarity and conciseness.

The features described herein be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

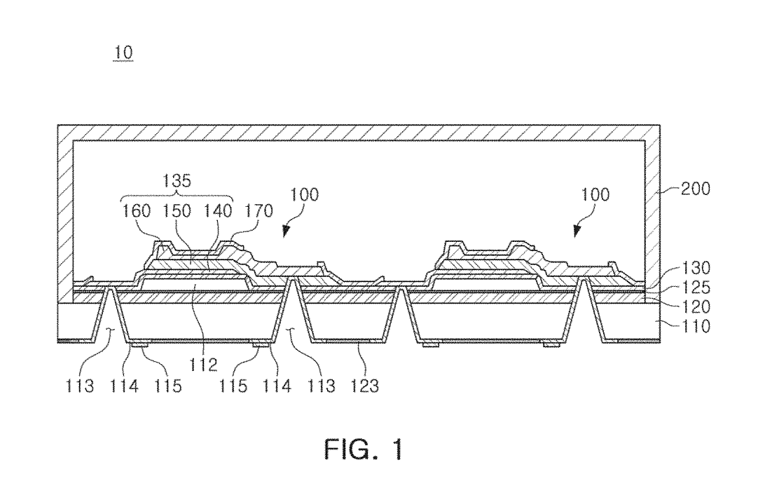

FIG. 1 is a cross-sectional view illustrating an example of a filter.

Referring to FIG. 1, a filter 10 includes a plurality of bulk acoustic-wave resonators 100 and a cap 200. The bulk acoustic-wave resonator 100 may be a film bulk acoustic resonator (FBAR).

The bulk acoustic-wave resonator 100 is configured by a multilayer structure including a plurality of films. The bulk acoustic-wave resonator 100 includes a substrate 110, an insulating layer 120, an air cavity 112, and a resonating part 135.

The substrate 110 may be formed of silicon (Si), and the insulating layer 120 that electrically insulates the resonating part 135 from the substrate 110 is formed on a top surface of the substrate 110. The insulating layer 120 is formed on the substrate 110 by performing chemical vapor deposition, RF magnetron sputtering, and evaporation for one of silicon dioxide (SiO₂) and aluminum oxide (Al₂O₂).

The air cavity 112 is disposed over the insulating layer 120. The air cavity 112 is disposed below the resonating part 135 so that the resonating part 135 vibrates in a predetermined direction. The air cavity 112 is formed by operations of forming an air cavity sacrificial layer pattern on the insulating layer 120, forming a membrane 130 on the air cavity sacrificial layer pattern, and then etching and removing the air cavity sacrificial layer pattern. The membrane 130 serves as an oxidation protective film or serve as a protective layer protecting the substrate 110.

An etching stop layer 125 is additionally formed between the insulating layer 120 and the air cavity 112. The etching stop layer 125 serves to protect the substrate 110 and the insulating layer 120 from the etching operation, and serves as a base necessary to deposit various other layers on the etching stop layer 125.

The resonating part 135 includes a first electrode 140, a piezoelectric layer 150, and a second electrode 160 which are sequentially stacked on the membrane 130. A common region of the first electrode 140, the piezoelectric layer 150, and the second electrode 160 which are overlapped in a vertical direction are positioned above the air cavity 112. The first electrode 140 and the second electrode 160 may be formed of one of gold (Au), titanium (Ti), tantalum (Ta), molybdenum (Mo), ruthenium (Ru), platinum (Pt), tungsten (W), aluminum (Al), iridium (Ir), and nickel (Ni), or alloys thereof.

The piezoelectric layer 150, which is a portion making a piezoelectric effect that converts electrical energy into mechanical energy in a form of an elastic wave, may be formed of one of aluminum nitride (AlN), zinc oxide (ZnO), and lead zirconium titanium oxide (PZT; PbZrTiO). In addition, the piezoelectric layer 150 may further include a rare earth metal. As an example, the rare earth metal includes at least one of scandium (Sc), erbium (Er), yttrium (Y), and lanthanum (La). The piezoelectric layer 150 include the rare earth metal by 1 to 20 at %.

A seed layer for improving crystal orientation of the piezoelectric layer 150 may be additionally disposed below the first electrode 140. The seed layer may be formed of one of aluminum nitride (AlN), zinc oxide (ZnO), and lead zirconium titanium oxide (PZT; PbZrTiO) which have the same crystallinity as the piezoelectric layer 150.

The resonating part 135 is partitioned into an active area and an inactive area. The active area of the resonating part 135 refers to an area that vibrates and resonates in a predetermined direction by a piezoelectric phenomenon occurring in the piezoelectric layer 150 when electrical energy such as a radio frequency signal is applied to the first electrode 140 and the second electrode 160, and corresponds to an area in which the first electrode 140, the piezoelectric layer 150, and the second electrode 160 overlap in a vertical direction above the air cavity 112. The inactive area of the resonating part 135 refers to an area that does not resonate by the piezoelectric phenomenon even when electrical energy is applied to the first electrode 140 and the second electrode 160, and corresponds to an area out of the active area.

The resonating part 135 outputs the radio frequency signal having a specific frequency using the piezoelectric phenomenon. Specifically, the resonating part 135 outputs the radio frequency signal having a resonance frequency corresponding to the vibration according to the piezoelectric phenomenon of the piezoelectric layer 150.

The protective layer 170 is disposed on the second electrode 160 of the resonating part 135 to prevent the second electrode 160 from being externally exposed. The protective layer 170 is formed of any one of insulating material of silicon oxide based insulating material, a silicon nitride based insulating material, and an aluminum nitride based insulating material.

At least one via hole 113 penetrating through the substrate 110 in a thickness direction of the substrate 110 is formed in a lower surface of the substrate 110. The via hole 113 penetrates through some of the insulating layer 120, the etching stop layer 125, and the membrane 130 in the thickness direction, other than the substrate 110. A connection pattern 114 is formed in the via hole 113, and is formed on an entirety of an inner surface, that is, an inner wall of the via hole 113.

The connection pattern 114 is manufactured by forming a conductive layer on the inner surface of the via hole 113. In one example, the connection pattern 114 is formed by depositing, coating, or filling any one or any combination of conductive metal of gold (Au), copper (Cu), and an alloy of titanium (Ti)-copper (Cu) along the inner wall of the via hole 113.

The connection pattern 114 is connected to one or both of the first electrode 140 and the second electrode 160. As an example, the connection pattern 114 penetrates through at least a portion of the substrate 110, the membrane 130, the first electrode 140, and the piezoelectric layer 150, and is electrically connected to at least one of the first electrode 140 and the second electrode 160. The connection pattern 114 formed on the inner surface of the via hole 113 is extended to the lower surface of the substrate 110, and is connected to a substrate connection pad 115 provided on the lower surface of the substrate 110. Thereby, the connection pattern 114 electrically connects the first electrode 140 and the second electrode 160 to the substrate connection pad 115.

The substrate connection pad 115 is electrically connected to an external substrate which is disposed below the filter 10 using a bump. The bulk acoustic-wave resonator 100 performs a filtering operation of the radio frequency signal by the signal applied to the first and second electrodes 140 and 160 through the substrate connection pad 115.

The cap 200 is bonded to the multilayer structure, forming a plurality of bulk acoustic-wave resonators 100, to protect the plurality of bulk acoustic-wave resonators 100 from an external environment. The cap 200 is formed to have an internal space in which the plurality of bulk acoustic-wave resonators 100 are accommodated. The cap 200 may be formed in a shape of a hexahedron of which a bottom surface is opened, and may thus include a top surface and a plurality of side surfaces connected to the top surface.

The cap 200 has an accommodating part formed at the center so as to accommodate the resonating part 135 of the plurality of bulk acoustic-wave resonators 100, and has an edge formed to be stepped, as compared to the accommodating part, so as to be bonded to a bonding region of the multilayer structure. The bonding region of the multilayer structure may correspond to an edge of the multilayer structure.

The cap 200 is bonded to the substrate 110 stacked on the substrate 110. In addition, the cap 200 is bonded to at least one of the protective layer 170, the membrane 130, the etching stop layer 125, and the insulating layer 120, other than the substrate 110.

Conventionally, the cap 200 was formed of silicon (Si), and bonded to the multilayer structure through eutectic bonding. At the time of eutectic bonding, a bonding line formed in the bonding region between the cap formed of silicon (Si) and the substrate 110 provides a reference potential such as a ground potential. However, since the bonding line, providing the reference potential, causes parasitic inductance and an unnecessary coupling path in the bulk acoustic-wave resonator, and degrades overall performance of the filter, improvement is needed.

The cap 200, according an example in the present disclosure, is formed of glass to remove the parasitic inductance and the unnecessary coupling path caused by the bonding line. In this case, the cap 200 and the multilayer structure are bonded though anodic bonding.

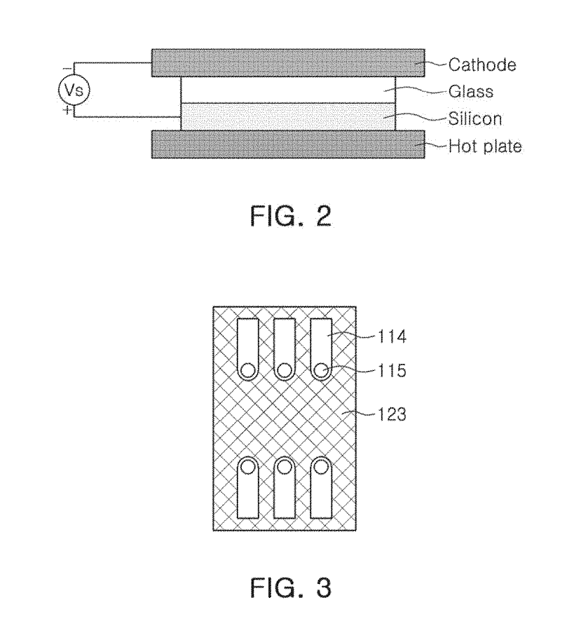

FIG. 2 is a view provided to illustrate anodic bonding. In the anodic bonding operation, voltage is applied to the cap 200 and the multilayer structure in a state in which heat is applied thereto, such that the cap 200 and the multilayer structure that correspond to bonding objects are directly bonded without the intervention of an intermediate medium. The anodic bonding operation removes the bonding line formed during eutectic bonding.

Specifically, referring to FIG. 2, the bonding objects are bonded by applying a voltage Vs to the bonding objects through a cathode after glass and silicon, that correspond to the bonding objects, are disposed on a hot plate. In this case, the bonding objects are bonded by applying heat and voltage to the bonding objects for a predetermined time in a range of temperature of about 180 to 500° C. and a range of voltage of about 200 to 1000V. The predetermined time may correspond to about 5 to 10 minutes, and the anodic bonding may be performed in vacuum.

In order to increase bonding performance between the bonding objects, surface states of the bonding objects may need to be adjusted. In addition, since a direct bonding between different materials is performed, thermal expansion coefficients between the bonding objects may need to be similar to each other. In a case in which the temperature at which bonding occurs is increased, since thermal stress occurs due to a thermal expansion coefficient difference between the bonding objects, the bonding operation may be generally performed at a temperature below 450° C. That is, the anodic bonding may be performed at a temperature region similar to 363° C., which is the temperature at which eutectic bonding occurs.

FIG. 3 is a bottom view of a substrate.

Referring to FIGS. 1 and 3, a shielding layer 123 for blocking electromagnetic interference that occurs when the filter 10 is mounted on an external substrate is provided on the lower surface of the substrate 110 of the bulk acoustic-wave resonator 100. The shielding layer 123 is provided on the lower surface of the substrate 110 to provide a reference potential such as the ground potential, thereby preventing a coupling between the bulk acoustic-wave resonator 100 and the external substrate. As an example, the shielding layer 123 is formed in an electrode having a mesh structure, and the shielding layer 123 is formed on an entire lower surface of the substrate 110 except for a region on which the connection pattern 114 and the substrate connection pad 115 are formed.

According to the example, a sealed bonding capable of securing long-term real world applications can be implemented by bonding the substrate 110 of the bulk acoustic-wave resonator 100 to the cap 200 formed of the glass using anodic bonding, which has bonding properties stronger than eutectic bonding. In addition, a stable and uniform reference potential (reference GND) for wafer level test is maintained through the shielding layer 123 formed on the lower surface of the substrate 110. Further, the capacitive coupling occurring between the external substrate and the filter including the plurality of bulk account resonators is effectively blocked, and consequently, the external substrate and the filter may be separately designed.

In the above description, although the cap 200, according to the example, is formed of glass, the cap 200 may be formed of a polymer other than the glass. In addition, although the shielding layer 123 is described in the example as being formed in an electrode having a mesh structure, the shielding layer 123 may also be formed in an electrode of a solid form. The cap formed of glass or polymer, and the electrode configured in a mesh or solid form may be applied to various examples in the present disclosure.

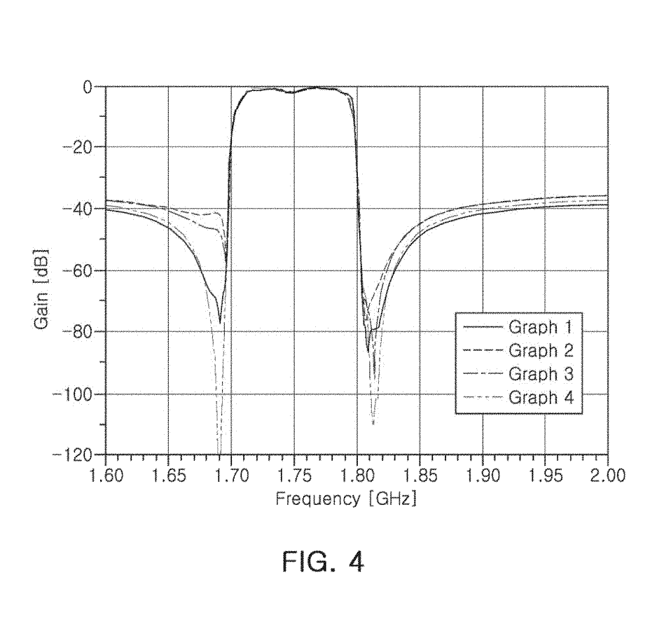

FIG. 4 illustrates a simulation result of an example in the present disclosure.

In FIG. 4, a first graph (Graph 1) illustrates a simulation graph of a modified Butterworth-Van-Dyke (mBVD) model according to a comparative example, a second graph (Graph 2) illustrates a graph according to a measurement result of a filter which is actually manufactured according to the comparative example, a third graph (graph 3) illustrates a graph according to an electromagnetic (EM) simulation result according to the comparative example, and a fourth graph (Graph 4) illustrates a graph according to an EM simulation result according to an example in the present disclosure. In this case, the comparative example is a filter in which the cap, formed of silicon, is bonded to the substrate through eutectic bonding, and the shielding layer is not provided on the lower surface of the substrate.

The EM simulation result was performed under wafer level test (WLT) conditions. Here, the wafer level test (WLT) refers to directly measuring filter characteristics by a ground-signal-ground (GSG) probe, or the like using a wafer level package (WLP) pad exposed from a bottom surface in a wafer level, before a solder bump ball is configured in the filter. Therefore, in the view of the filter circuit model, the wafer level test confirms the filter characteristics by terminating input and output terminals of the filter at 50 ohms without a matching inductor in a state at which a shunt terminal of the filter is directly connected to a ground (GND).

First, when the first graph (Graph 1) and the third graph (Graph 3) are compared with each other based on the second graph (Graph 2), it is seen that the third graph (Graph 3) is more similar to the second graph (Graph 2) than the first graph (Graph 1). This is due to the parasitic inductance and the parasitic capacitance of the layout or interconnection of the bulk acoustic-wave resonator which are not reflected in the mBVD model of the first graph (Graph 1) are reflected in the EM simulation. That is, it is seen that the mBVD model has a certain difference from the measurement result of the actually manufactured filter.

The fourth graph (Graph 4), based on an EM simulation result of an example described in this application, is very similar to the first graph (Graph 1). Thus, confirming that the parasitic inductance and the parasitic capacitance of described examples, which are not reflected in the mBVD model, are effectively blocked. Therefore, from the above result, a case in which the external substrate and the filter are separately designed obtains a result similar to a case in which the external substrate and the filter are integrally designed.

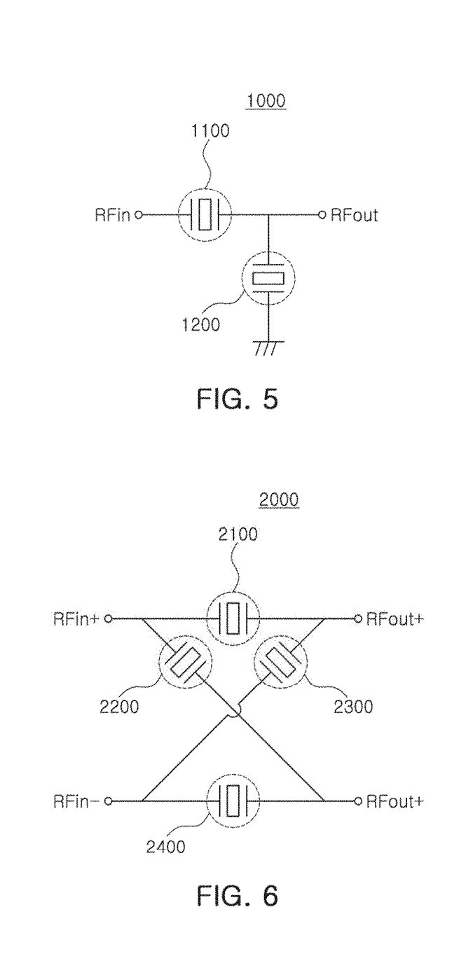

FIGS. 5 and 6 are schematic circuit diagrams of a filter according to examples in the present disclosure. Each of a plurality of bulk acoustic-wave resonators employed in the filter of FIGS. 5 and 6 may be formed by electrically connecting the bulk acoustic-wave resonators according to various examples in the present disclosure.

Referring to FIG. 5, a filter 1000 in the present disclosure is formed in a ladder-type filter structure. Specifically, the filter 1000 includes a plurality of bulk acoustic-wave resonators 1100 and 1200.

The first bulk acoustic-wave resonator 1100 is connected in series between a signal input terminal to which an input signal RFin is input and a signal output terminal from which an output signal RFout is output. The second bulk acoustic-wave resonator 1200 is connected between the signal output terminal and a ground. Referring to FIG. 6, a filter 2000 in the present disclosure is formed in a lattice-type filter structure. Specifically, the filter 2000 includes a plurality of bulk acoustic-wave resonators 2100, 2200, 2300, and 2400 to filter balanced input signals RFin+ and RFin− to output balanced output signals RFout+ and RFout−.

As set forth above, according to the examples in the present disclosure, a sealed bonding capable of securing long-term real world applications can be implemented by bonding a cap using anodic bonding, which has strong bonding property. In addition, the stable and uniform reference potential for the wafer level test may be provided through the shielding layer formed on the lower surface of the substrate. Further, the capacitive coupling occurring between the external substrate and the filter including the plurality of bulk account resonators may be effectively blocked, and consequently, the external substrate and the filter may be separately designed.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A filter, comprising:
a multilayer structure comprising films configured as bulk acoustic-wave resonators; and
a cap member formed of glass or polymer, configured to accommodate the bulk acoustic-wave resonators, and bonded to the multilayer structure.

2. The filter of claim 1, wherein the films comprise a substrate, and a first electrode, a piezoelectric layer, and a second electrode, stacked on the substrate.

3. The filter of claim 2, wherein the substrate is formed of silicon.

4. The filter of claim 3, wherein the cap member is directly bonded to the substrate.

5. The filter of claim 3, wherein the cap member and the substrate are bonded to each other through anodic bonding.

6. The filter of claim 2, further comprising:
a shielding layer provided on a lower surface of the substrate.

7. The filter of claim 6, wherein the shielding layer is formed in an electrode having a mesh structure.

8. The filter of claim 6, wherein the shielding layer is configured to provide a reference potential.

9. A filter, comprising:
a multilayer structure configured as bulk acoustic-wave resonators, each of the bulk acoustic-wave resonators comprising a substrate, a first electrode, a piezoelectric layer, and a second electrode, stacked on the substrate,
a cap member configured to accommodate the bulk acoustic-wave resonators, and bonded to the multilayer structure; and
a shielding layer configured on a lower surface of the substrate.

10. The filter of claim 9, wherein the shielding layer is formed in an electrode having a mesh structure.

11. The filter of claim 9, wherein the shielding layer is formed in an electrode having a solid structure.

12. The filter of claim 9, wherein the shielding layer provides a reference potential.

13. The filter of claim 12, wherein the reference potential corresponds to a ground potential.

14. The filter of claim 9, wherein the cap member and the substrate are directly bonded to each other through anodic bonding.

15. The filter of claim 13, wherein the cap member is formed of glass.

16. The filter of claim 13, wherein the substrate is formed of silicon.

17. The filter of claim 13, wherein the cap member is formed of polymer.

18. A filter, comprising:
a substrate;
bulk acoustic-wave resonators disposed on the substrate; and
a cap member formed of glass disposed to accommodate and seal the bulk acoustic-wave resonators, and bonded to the substrate.

19. The filter of claim 18, further comprising:
a shielding layer having a mesh structure disposed on a lower surface of the substrate.

20. The filter of claim 19, wherein the cap member and the substrate are bonded to each other through anodic bonding.
